(19) United States
(12) Patent Application Publication
(10) Pub. No.: US 2012/0048355 A1
(43) Pub. Date: Mar. 1, 2012

(54) SEMICONDUCTOR DEVICE MODULE PACKAGE STRUCTURE AND SERIES CONNECTION METHOD THEREOF

(75) Inventors: Hsin-Hsin Hsieh, Taipei City (TW); Chi-Shiung Hsi, Taipei County (TW); Tao-Chih Chang, Taoyuan County (TW)

(73) Assignee: INDUSTRIAL TECHNOLOGY RESEARCH INSTITUTE, Hsinchu (TW)

(21) Appl. No.: 12/982,121

(22) Filed: Dec. 30, 2010

(30) Foreign Application Priority Data
Aug. 27, 2010 (TW) TW099128791

(51) Int. Cl. H01L 31/0248; H01L 31/18

(52) U.S. Cl. 136/252; 438/64; 257/E31.001

(57) ABSTRACT

The invention provides a semiconductor device module package structure and a series connection method thereof. The semiconductor device module package structure includes a wafer having a plurality through holes. A doped layer covers a top surface of the first electrode, and inner sidewalls extending to a bottom surface of the first electrode. At least two first electrodes are disposed adjacent to each other and on opposite sides of the through holes. A second electrode covers the doped layer and the through holes. At least two insulating layer patterns overlap with the first and second electrodes. A second electrode conductive pattern is disposed on the second electrode. The second electrode conductive pattern is disposed between the insulating layer patterns, electrically connecting to the second electrode.

### CROSS REFERENCE TO RELATED APPLICATIONS

This application claims priority of Taiwan Patent Application No. 099128791, filed on Aug. 27, 2010, the entirety of which is incorporated by reference herein.

### BACKGROUND OF THE INVENTION

1. Field of the Invention

The present invention relates to a semiconductor device module package structure and series connection method thereof, and in particular, to a solar cell module package structure and series connection method thereof.

2. Description of the Related Art

For the conventional solar cell module package structure fabrication process, a package loss problem occurs due to increased shunt resistance (Rsh) and reduced series resistance (Rs). Thus, the conventional solar cell module package structure fabrication process requires an anode and a cathode to be effectively isolated to prevent reduction in power due to shunting.

To reduce package loss, a solar cell, for example, a back-contact solar cell, with electrodes disposed on a same surface uses solder or conductive glue for current conduction. Note that the back-contact solar cell usually suffers from a power reduction problem due to shunting

Thus, a novel solar cell module package structure is desired to prevent power reduction due to shunting.

### BRIEF SUMMARY OF INVENTION

A semiconductor device module package structure and a series connection method thereof are provided. An exemplary embodiment of a dye-sensitized solar cell comprises a semiconductor device module package structure comprising at least one semiconductor device unit having a top surface and a bottom surface, wherein the semiconductor device unit comprises a wafer having a plurality through holes. A doped layer covers a top surface of the semiconductor device, and inner sidewalls of the through holes extending to a portion of a bottom surface of the wafer. At least two first electrodes are disposed on the bottom surface of the wafer and respectively on opposite sides of the through holes. A second electrode is disposed on the bottom surface of the wafer, covering the doped layer and the through holes; and at least two insulating layer patterns are disposed on the bottom surface of the semiconductor device unit, overlapping a portion of one of the first electrodes and a portion of the second electrode. A second electrode conductive layer pattern is disposed between the insulating layer patterns, electrically connecting to the second electrode.

An exemplary embodiment of a series connection method of a semiconductor device module package structure, comprises providing at least two semiconductor device module package structures, wherein each comprises at least one semiconductor device unit having a top surface and a bottom surface, wherein the semiconductor device unit comprises a wafer having a plurality through holes. A doped layer covers a top surface of the semiconductor device, and inner sidewalls of the through holes extending to a portion of a bottom surface of the wafer. At least two first electrodes are disposed on the bottom surface of the wafer and respectively on opposite sides of the through holes. A second electrode is disposed on the bottom surface of the wafer, covering the doped layer and the through holes; and at least two insulating layer patterns are disposed on the bottom surface of the semiconductor device unit, overlapping a portion of one of the first electrodes and a portion of the second electrode. A second electrode conductive layer pattern is disposed between the insulating layer patterns, electrically connecting to the second electrode. The first electrode conductive layer patterns of one of the semiconductor device module package structures is connected to the second electrode conductive layer patterns of another one of the semiconductor device module package structures along a series connected direction to form a connection portion.

Another exemplary embodiment of a series connection method of a semiconductor device module package structure, comprises providing at least two semiconductor device module package structures, wherein each comprises at least one semiconductor device unit having a top surface and a bottom surface, wherein the semiconductor device unit comprises a wafer having a plurality through holes. A doped layer covers a top surface of the semiconductor device, and inner sidewalls of the through holes extending to a portion of a bottom surface of the wafer. At least two first electrodes disposed on the bottom surface of the wafer, wherein the through holes are exposed from the first electrodes. A second electrode is disposed on the bottom surface of the wafer, covering the doped layer and the through holes; and at least two insulating layer patterns are disposed on the bottom surface of the semiconductor device unit, overlapping a portion of one of the first electrodes and a portion of the second electrode. A second electrode conductive layer pattern is disposed between the insulating layer patterns, electrically connecting to the second electrode. The first electrode conductive layer patterns of one of the semiconductor device module package structures is connected to the second electrode conductive layer patterns of another one of the semiconductor device module package structures along a series connected direction to form a connection portion.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIGS. 1˜2a, 3˜6a, 7a, 8˜11a and 12 are cross section views for fabricating one exemplary embodiment of a semiconductor device module package structure of the invention.

FIGS. 2b and 7b are top views of FIGS. 2a and 7a.

FIGS. 6b and 11b are bottom views of FIGS. 6a and 11a.

FIGS. 13a and 13b illustrate exemplary embodiments of a series connection method of semiconductor device module package structures.

FIGS. 14a to 14c illustrate various exemplary embodiments of a series connection method of semiconductor device module package structures.

### DETAILED DESCRIPTION OF INVENTION

The following description is a mode for carrying out the invention. This description is made for the purpose of illustrating the general principles of the invention and should not be taken in a limiting sense. The scope of the invention is best determined by reference to the appended claims. Wherever possible, the same reference numbers are used in the drawings and the descriptions to refer the same or like parts.

The present invention will be described with respect to particular embodiments and with reference to certain drawings, but the invention is not limited thereto and is only limited by the claims. The drawings described are only schematic and are non-limiting. In the drawings, the size of some of the elements may be exaggerated and not drawn to scale for illustrative purposes. The dimensions and the relative dimensions do not correspond to actual dimensions to practice of the invention.

One exemplary embodiment of a solar cell module package structure is provided. The solar cell module package structure uses an insulating material covering a position connected with an anode electrode and a cathode electrode of the solar cell (but not covering the entire areas of the electrodes). The insulating material prevents shunting by the anode electrode and the cathode electrode connecting to each other. Conductive layer patterns are then coated or soldered on the electrodes, thereby significantly reducing the package loss of the solar cell module package structure.

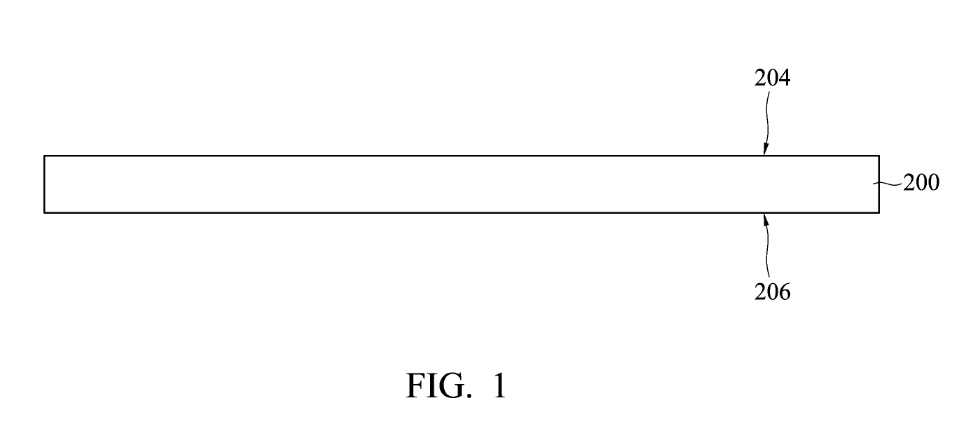

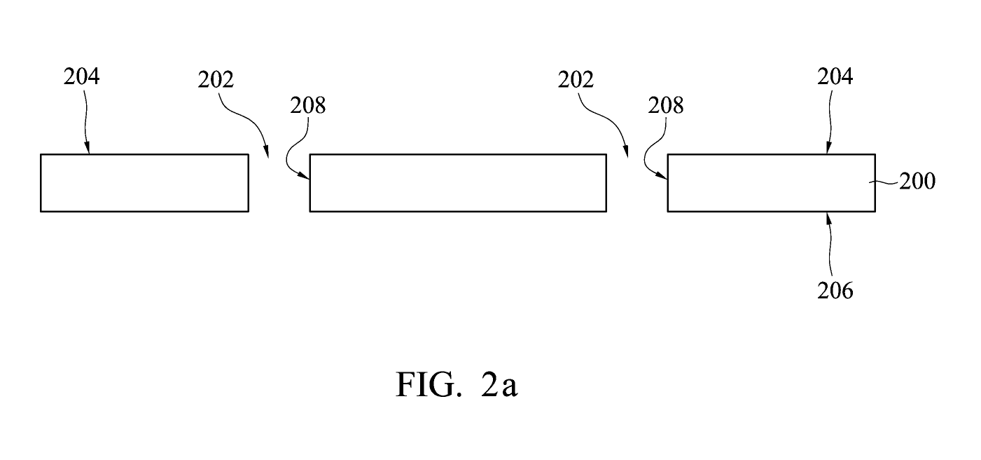

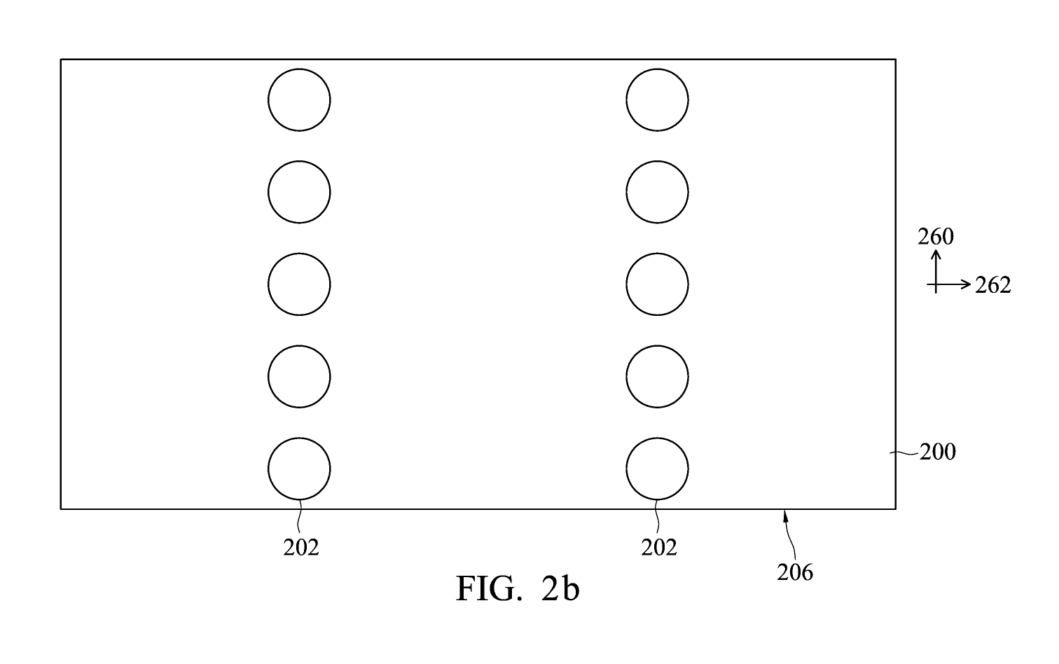

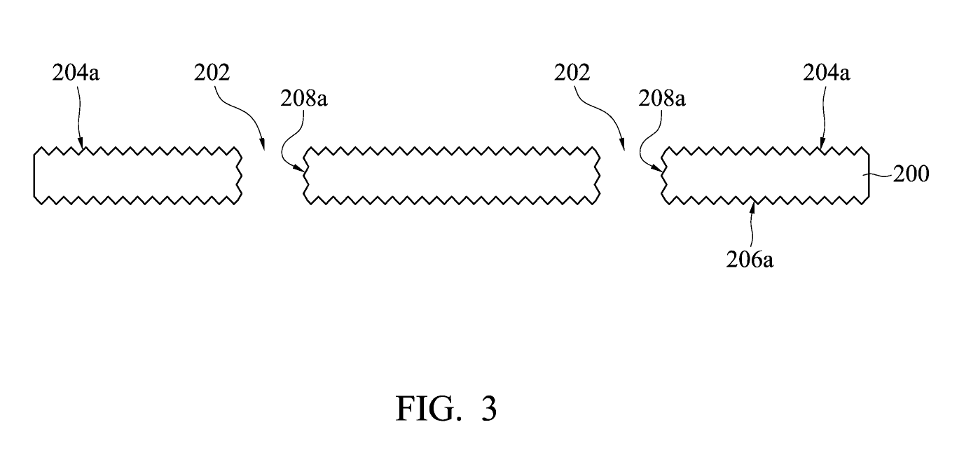

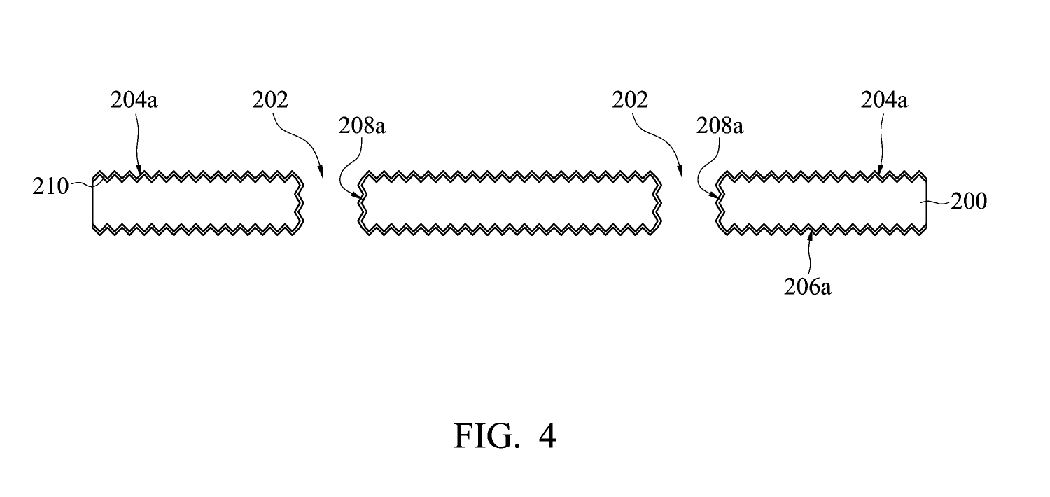

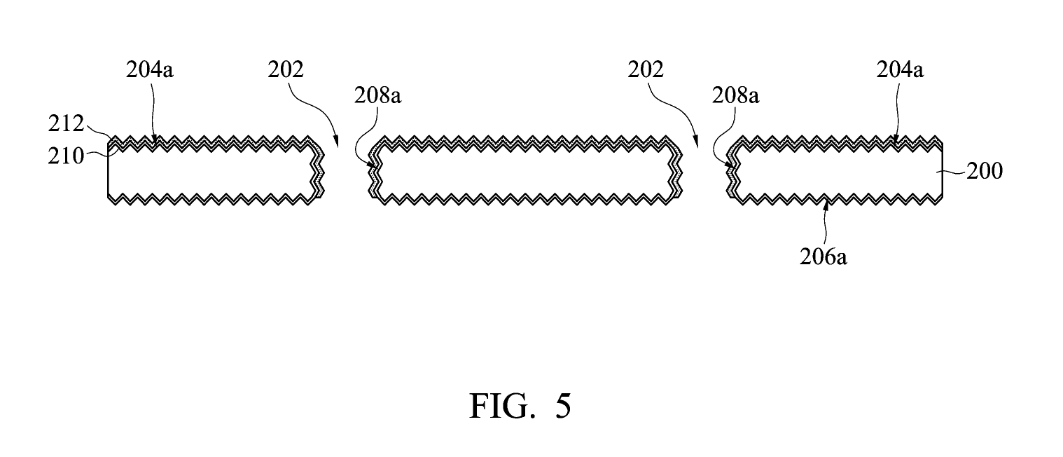

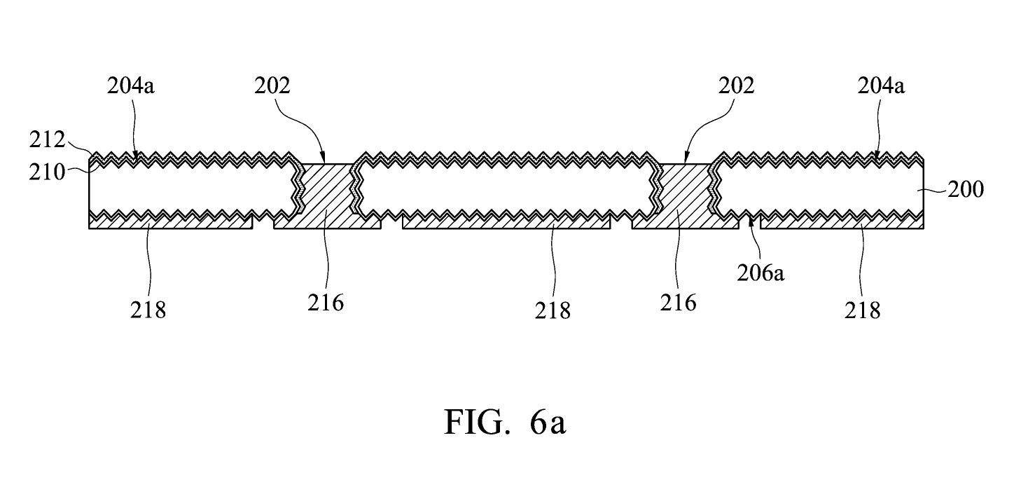

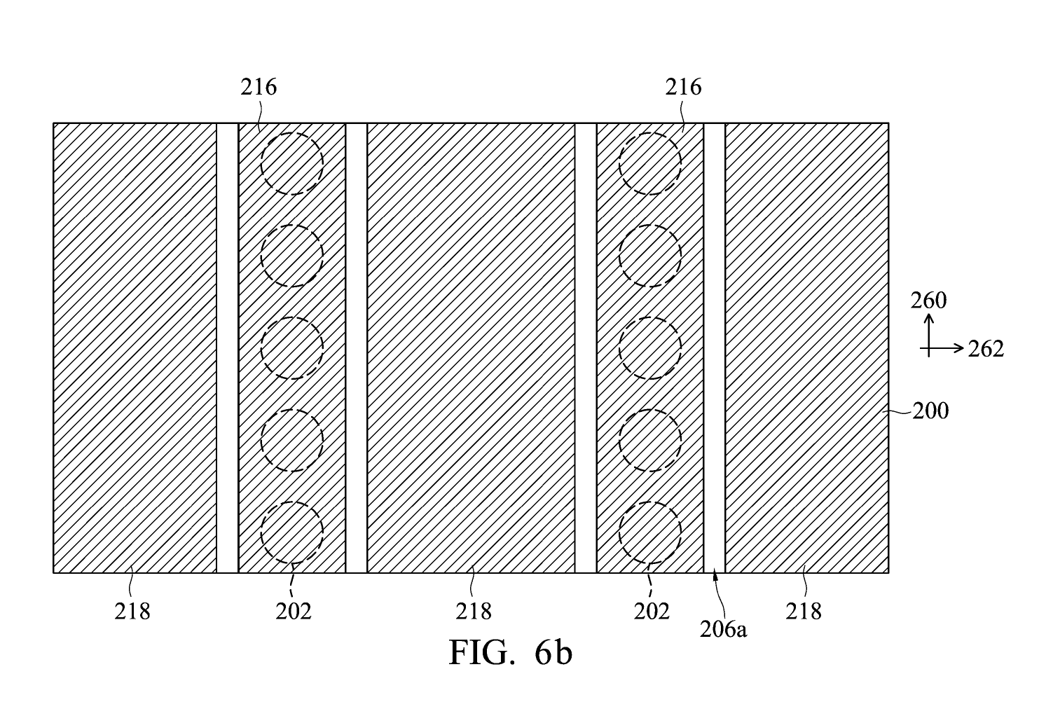

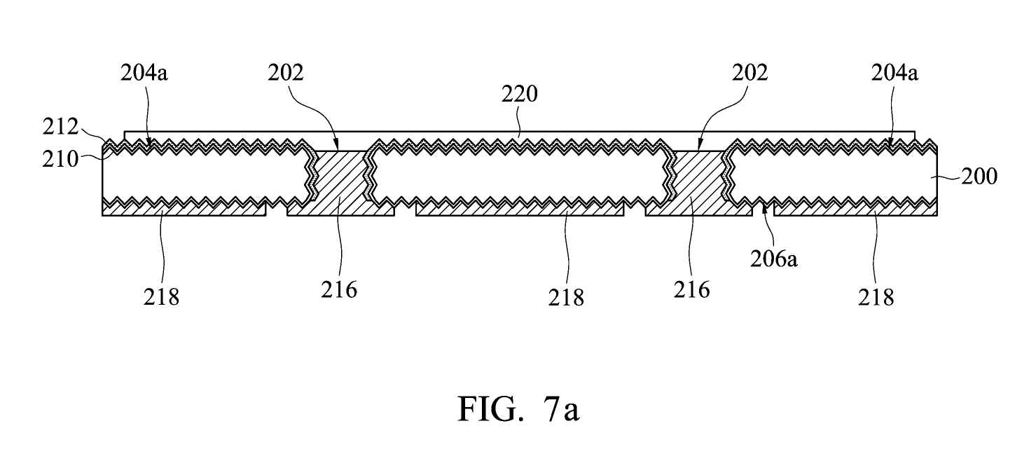

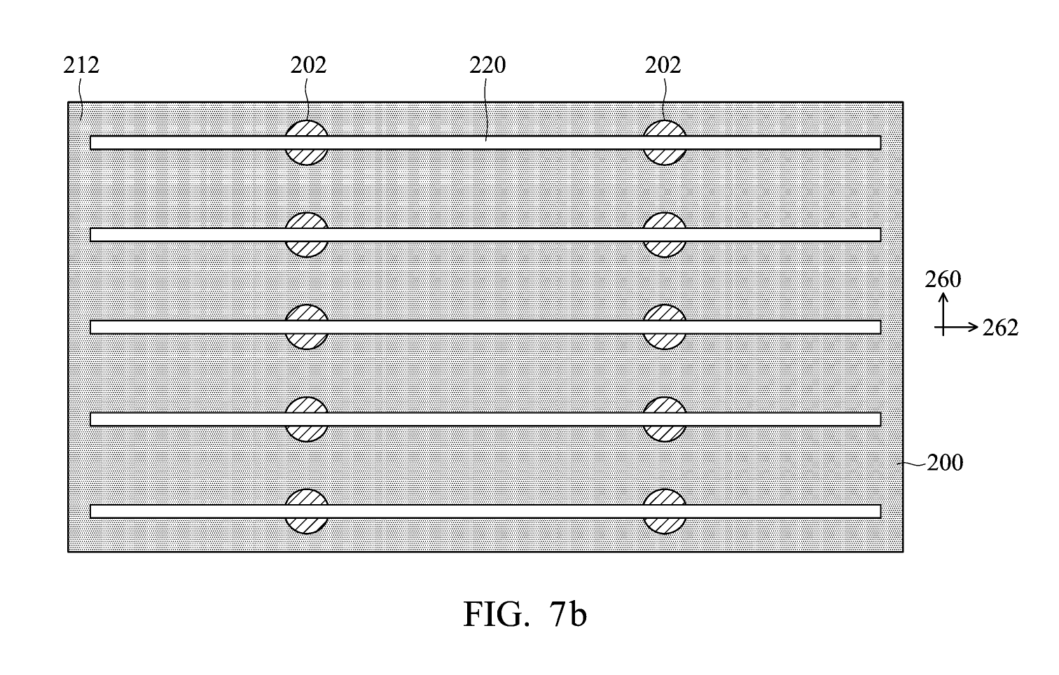

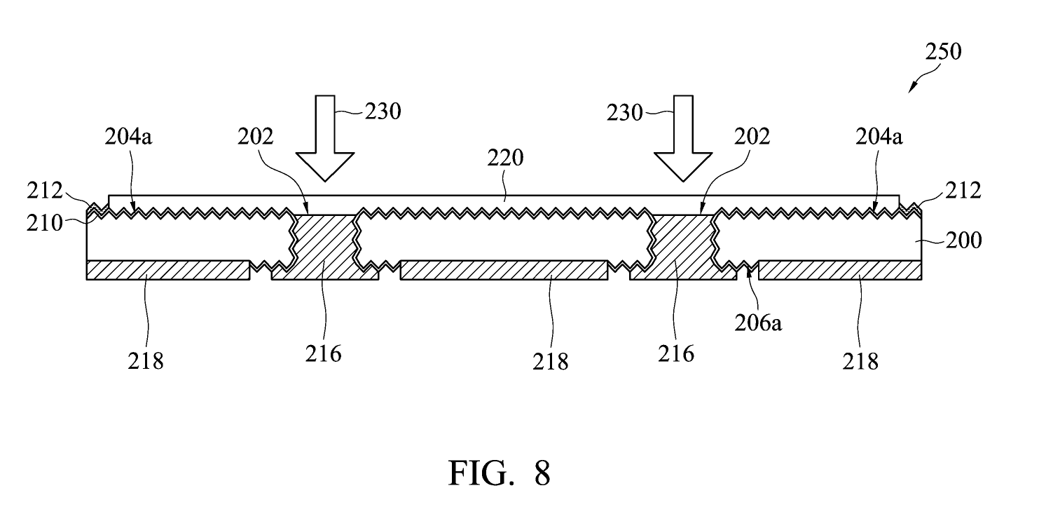

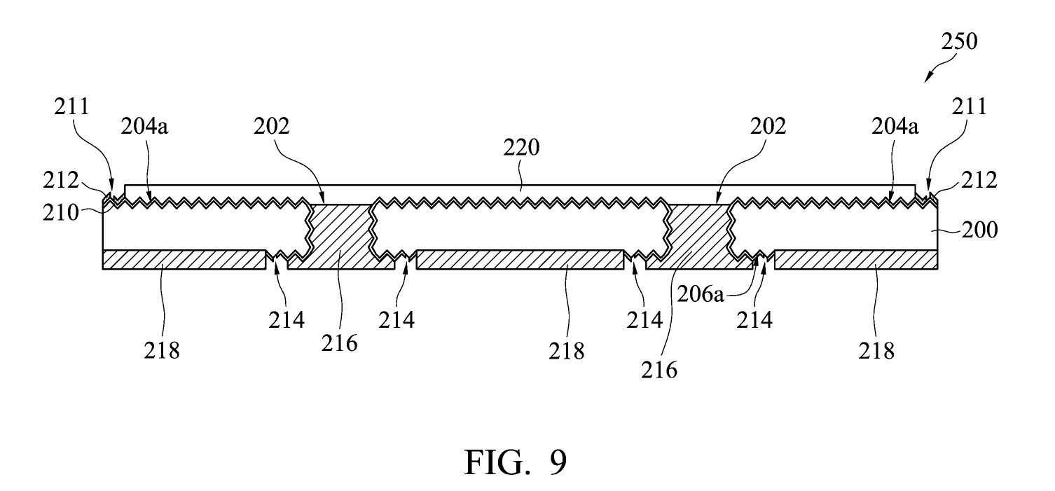

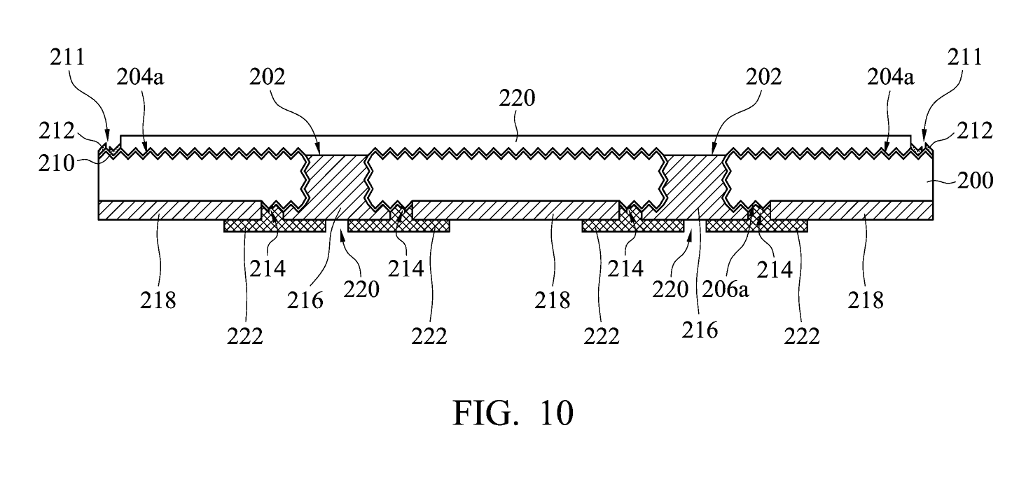

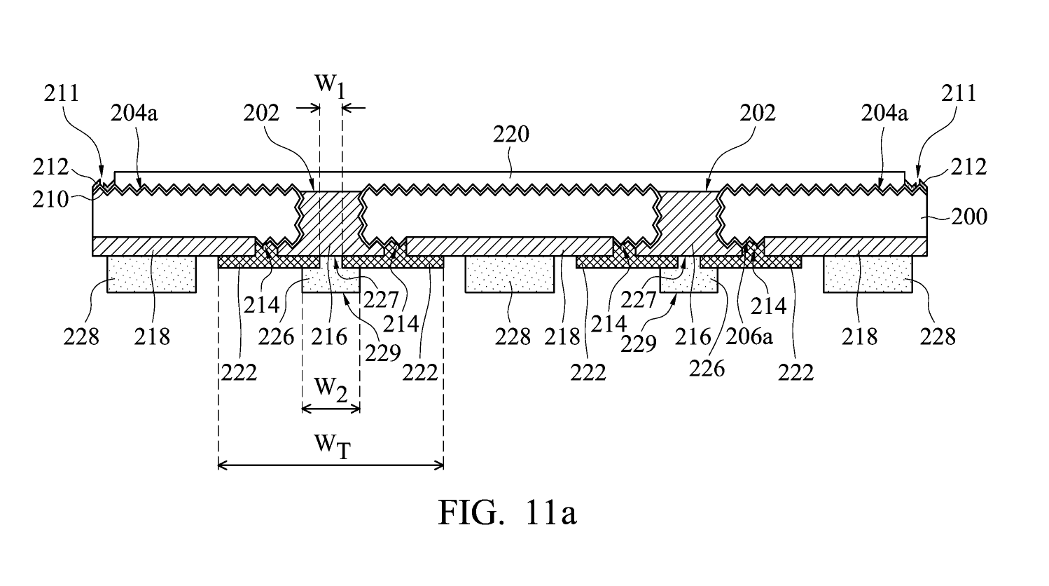

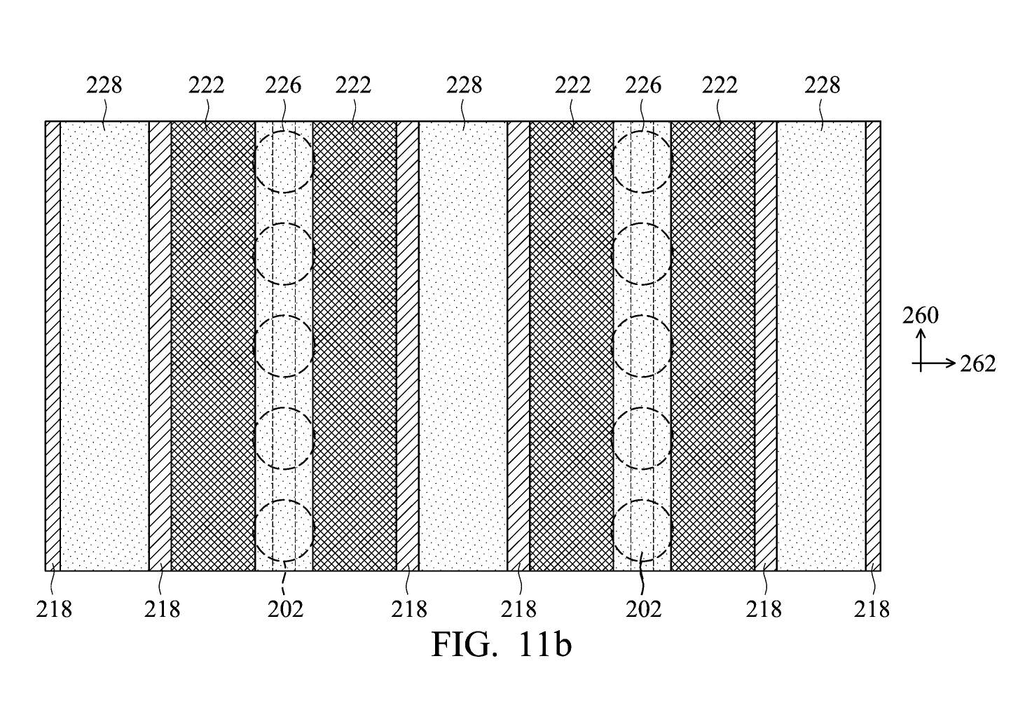

FIGS. 1˜2a, 3˜6a, 7a, 8˜11a and 12 are cross section views for fabricating one exemplary embodiment of a semiconductor device module package structure 500 of the invention. FIGS. 2b and 7b are top views of FIGS. 2a and 7a. FIGS. 6b and 11b are bottom views of FIGS. 6a and 11a. One exemplary embodiment of a semiconductor device module package structure 500 is described using a method for fabricating a metal wrapped through (MWT) solar cell module package structure as an example. However, the type of solar cell module package structure is not limited thereto. Please refer to FIG. 1, wherein first, a wafer 200 is provided. In one embodiment, the wafer 200 is a p-type silicon wafer having a top surface 204 and a bottom surface 206, wherein the top surface 204 is used as an illuminated surface of a semiconductor device module package structure 500 such as a solar cell module package structure. Next, the wafer 200 is subjected to a wafer cleaning process. In one embodiment, the wafer may be cleaned using NaOH or KOH solutions.

Please refer to FIGS. 2a and 2b, a plurality of through holes 202 with a small size is formed through the wafer 200 along a direction 260 using a laser drilling method. As shown in FIG. 2b, the through holes 202 are arranged as rows along the direction 260. As shown in FIG. 2b, the number of rows of the through holes 202 is two. However, the number of rows is not limited thereto. In one embodiment, the through holes 202 are used for conduction of subsequently formed conducting layer patterns from the top surface 204 to the bottom surface 206 of the wafer 200. The diameter of the through holes 202 may be between 50 μm to 100 μm.

Please refer to FIG. 3, wherein next, a texture treatment process may be performed on the top surface 204, the bottom surface 206 of the wafer 200 and sidewalls 208 of the through holes 202 as shown in FIG. 2a using an anisotropic etching method. In one embodiment, the texture treatment process may be performed using a solution of NaOH and isopropyl alcohol (IPA) to anisotropic etch a (100) surface of the wafer 200, for example, a silicon wafer, thereby exposing a <111> crystal plane of the silicon wafer. After performing the texture treatment process, the top surface 204a and bottom surface 206a of the wafer 200 and sidewalls 208a of the through holes 202 may have a pyramid-like shape. Also, the texture treatment process may form sodium silicate on the top surface 204a and bottom surface 206a of the wafer 200 and sidewalls 208a of the through holes 202. The texture treatment process is used to reduce light reflection on the surface of the wafer 200. In one embodiment, the effect of the texture treatment process is affected by the cleanliness of the wafer, NaOH and IPA concentrations of the solution, the ratio between NaOH and IPA, the temperature of the solution, and reaction time. Also, the type of container used in the texture treatment process, the evaporation rate of IPA, and sodium silicate residue may all affect the result of the texture treatment process. Next, the wafer 200 may be subjected to a cleaning process. In one embodiment, an HPM cleaning solution (HCl/H₂O₂/H₂O with a 1:1:6 volume ratio) may be used to perform the cleaning process.

Please refer to FIG. 4, wherein next, an n-type doped layer 210 is formed entirely covering the top surface 204a and bottom surface 206a of the wafer 200 and sidewalls 208a of the through holes 202 using a diffusion, laser or deposition process, thereby entirely encapsulating the p-type wafer 200. In one embodiment, the n-type doped layer 210 may be a POCl₃ layer, and a thickness of the n-type doped layer 210 may be between 0.1 μm and 2 μm. In one embodiment, phosphorous silicate glass (PSG) may be formed on the surfaces of the wafer during formation of the n-type doped layer 210. Accordingly, an acid solution (such as HF) or a plasma process may be used to clean the surfaces of the wafer.

Please refer to FIG. 5, wherein next, an anti-reflection coating (ARC) 212 may be formed on the top surface 204a and bottom surface 206a of the wafer 200 and sidewalls 208a of the through holes 202 using a deposition process such as a plasma enhanced chemical vapor deposition (PECVD) process. In one embodiment, a reaction gas of SiH₄ and NH₃ or a reaction gas of SiH₄ and N₂ may be used in the PECVD process. In one embodiment, the anti-reflection coating (ARC) 212 may be SiN, reducing light reflection, thereby increasing light current. Also, the anti-reflection coating (ARC) 212 may serve as a protection layer, for example, the anti-reflection coating (ARC) 212 may be used to protect the semiconductor device module package, such as a solar cell module package. Also, the anti-reflection coating (ARC) 212 may have other functions such as scratch resistance and mist proof functions.

Please refer to FIGS. 6a and 6b, wherein next, a plurality of first electrodes 218 is formed on a portion of the bottom surface 206a of the wafer 200 extending along the direction 260 to connect to the bottom surface 206a of the wafer 200 by a screen printing, deposition or evaporation process. The first electrodes 218 are respectively formed on opposite sides of the through holes 202. During the screen printing, deposition or evaporation process, a second electrode 216 is also formed on a portion of the bottom surface 206a of the wafer 200 extending along the direction 260, covering a portion of the through holes 202 and the n-type doped layer 210. In one embodiment, a process sequence of forming the first electrodes 218 and the second electrode 216 may be exchanged. In one embodiment, the first electrodes 218 and the second electrode 216 are used to connect the wafer 200 and the n-type doped layer 210 to an external circuit. As shown in FIG. 6a, the first electrodes 218 and the second electrode 216 are arranged along a second direction 262, wherein two of the first electrodes 218 are respectively disposed on opposite sides of the second electrode 216, electrically isolated from the second electrode 216. In one embodiment, the second electrode 216 may entirely fill the through holes 202, covering the n-type doped layer 210 and the ARC layer 212 on the sidewalls of the through holes 202. Alternatively, if the resulting semiconductor device module package structure is an emitter wrapped through (EWT) cell module package structure, the second electrode 216 may not entirely fill the through holes 202. In one embodiment, the second electrode 216 may comprise a conductive glue, for example, a silver glue, having a conducting function to conducting the electrode from the front surface to the rear surface of the wafer.

Please refer to FIGS. 7a and 7b, wherein FIG. 7b is a top view showing the top surface 204a of the wafer 200. Next, a plurality of electron collection layer patterns 220 may be respectively formed on the through holes 202, extending to cover a portion of the top surface 204a of the wafer 200 along a direction 262 (wherein the direction 262 is different from the direction 260), covering the second electrode 216 on the through holes 202 by a print screening process. In one embodiment, the electron collection layer patterns 220 may be used to collect electrons conducted to the second electrode 216, wherein the second electrode 216 may comprise a conductive glue, for example, a silver glue. In one embodiment, the electron collection layer patterns 220 are disposed on an illuminated surface of the wafer 200 (top surface 204a) to increase the electron collection efficiency of the solar cell module package. It is understood that the electron collection layer patterns 220 have a function of collecting electrons conducted to the second electrode 216, and, the electron collection layer patterns 220 is not limited to the disclosed embodiments. Alternatively, the electron collection layer patterns 220 may be extended to cover a portion of the top surface 204a of the wafer 200 along both the directions 260 and 262, covering the second electrode 216 on the through holes 202. In another embodiment, a process sequence of FIGS. 6a, 6b and 7a, 7b may be exchanged.

Please refer to FIG. 8, wherein next, a co-firing process may be performed using an infrared ray oven, so that the electron collection layer patterns 220 and the second electrode 216 may diffuse through the ARC 212 to connect the n-type doped layer 210 on the bottom surface 206a of the wafer 200 and to connect the sidewalls of the through holes 202. The co-firing process may form an ohmic contact between the first electrodes 218 or the second electrode 216 and the elements contacted thereto. That is to say, during the co-firing process, the first electrodes 218 may be diffused through the n-type doped layer 210 to connect to the bottom surface 206a of the wafer 200, and the second electrode 216 may be connected to the n-type doped layer 210. In another embodiment, the co-firing process may have a temperature range of between 700° C. and 800° C., for example, 760° C. The description of one exemplary embodiment of a semiconductor device unit 250 (also serving as a back-contact solar cell 250) of the invention is completed. When the top surface 204a of the back-contact solar cell 250 is illuminated by a light 230, a p-n junction diode structure formed by the wafer 200 (p-type) and the n-type doped layer 210 may generate electrons and holes, thereby forming a current transmitted by the first electrodes 218 and the second electrode 216 on the bottom surface 206a of the back-contact solar cell 250. Thus, efficiency for one exemplary embodiment of a semiconductor device unit 250 is increased due to reduction of a light blocking region on an illuminated surface.

Please refer to FIG. 9, wherein next, openings 211 are formed in the a portion of the ARC 212 on the top surface 204a of the wafer 200 not covered by the electron collection layer patterns 220 (at outsides of the electron collection layer patterns 220, for example) by an etching process using a laser apparatus. Note that the etching process is performed to cut a portion of the n-type doped layer 210 on the bottom surface 206a of the wafer 200 not covered by the first electrodes 218 and the second electrode 216, thereby forming openings 214 in the ARC 212. The openings 211 in the ARC 212 may provide a good isolation on edges of the semiconductor device unit 250. Also, the openings 214 in the ARC 212 may provide a good isolation between the first electrodes 218 and the second electrode 216.

Please refer to FIG. 10, wherein next, at least two insulating layer patterns 222 are formed on a portion of the bottom surface 206a of the semiconductor device unit 250 by a spraying, screen printing, sticking or coating process, wherein the insulating layer patterns 222 overlap with the first electrodes 218 respectively on opposite sides of the through holes 202 and the adjacent second electrode 216. Therefore, the number of insulating layer patterns 222 may be at least two. As shown in FIG. 10, the insulating layer patterns 222 cover the n-type doped layer 210 on the bottom surface 206a of the wafer 200, overlapping with the first electrodes 218 and the second electrode 216. Also, any two of the insulating layer patterns 222 adjacent to each other have a space therebetween where the second electrode 216 is exposed from the insulating layer patterns 222. One exemplary embodiment of the insulating layer patterns 222 is used to separate subsequently formed conductive patterns electrically connecting to the first electrodes 218 and the second electrode 216 from each other to prevent the first electrodes 218 and the second electrode 216 from shunting to each other. In one embodiment, an overlapping area between each of the insulating layer patterns 222 and the first electrodes 218 or the second electrode 216 (also serving as an overlapping area between the insulating layer patterns and an anode or cathode of the back-contact solar cell 250) is about 5% to 90% of the total surface area of the first electrodes 218 or the second electrode 216. In one embodiment, the insulating layer patterns 222 may be formed of materials comprising thick film materials, for example, oxides, resin, epoxy, isolation paste or the like or combinations thereof. In one embodiment, the insulating layer patterns 222 may have a resistance which is larger than or equal to 10⁸ ohm, and insulating layer patterns 222 may have a low dielectric constant (k), such as less than or equal to 20. It is noted that the overlapping areas between each of the insulating layer patterns 222 and the first electrodes 218 or the second electrode 216 and the dielectric constant (k) of the insulating layer patterns 222 have a significant effect on the effectiveness of the isolation between the first electrodes 218 and the second electrode 216 and package loss (cells in a series connection) of the subsequently formed semiconductor device module package structure 500. For example, an overly small overlapping area between each of the insulating layer patterns 222 and the first electrodes 218 or the second electrode 216 or a overly large dielectric constant (k) of the insulating layer patterns 222 may result in shunting between the anode and the cathode of the solar cell, thereby increasing package loss (the cell in a series connection) of the solar cell module package structure.

Please refer to FIGS. 11a and 11b, wherein FIG. 11b is a bottom view showing the bottom surface 206a of the wafer 200. Next, a second electrode conductive layer pattern 226 is formed along the direction 260, on the second electrode 216 not covered by the insulating layer patterns by a spray, screen printing, sticking, coating or soldering process. Also, a plurality of first electrode conductive layer patterns 228, for example, at least two first electrode conductive layer patterns 228 (respectively on opposite sides of the second electrode conductive layer pattern 226), is formed extending on the bottom surface 206a of the wafer 200 along the direction 260 (leveled), covering the first electrodes 218. The first electrode conductive layer patterns 228 and the second electrode conductive layer pattern 226 respectively and electrically connect to the first electrodes 218 and the second electrode 216. As shown in FIGS. 11a and 11b, the second electrode conductive layer pattern 226 overlaps with the insulating layer patterns 222, wherein the second electrode conductive layer pattern 226 has a first surface 227, which electrically connects to the second electrode 216 and an opposite second surface 229. As shown in FIG. 11a, a width W₂ of the second surface 229 may be larger than or equal to a width W₁ of the first surface 227, so that a cross section of the second electrode conductive layer pattern 226 may be T-shaped. Additionally, a total width W_{T} of the adjacent insulating layer patterns 222 may be larger than or equal to the width W₂ of the second surface 229 because the second electrode conductive layer pattern 226 overlaps with only portions of the adjacent insulating layer patterns 222. In one embodiment, a current conducting surface (second surface 229) of the second electrode conductive layer pattern 226 may have a larger surface area than an electrode contact surface (the first surface 227) of the second electrode conductive layer pattern 226, thereby reducing the resistance thereof. Further, the second electrode conductive layer pattern 226 may be limited to a region occupied by the adjacent insulating layer patterns 222. Therefore, the first electrode conductive layer patterns 228 are respectively separated from the second electrode conductive layer pattern 226. The first electrodes 218 and the second electrode 216 may be prevented from electrically connecting and shunting to each other. Also, the insulating layer patterns 222 may increase position tolerance of the second electrode conductive layer pattern 226. Alternatively, the first electrode conductive layer patterns 228 may overlap with the insulating layer patterns 222. In this embodiment, the width W₂ of the second surface 229 of the second electrode conductive layer pattern 226 is smaller than the total width W_{T} of the adjacent insulating layer patterns 222, so that second electrode conductive layer pattern 226 does not electrically connect to the first electrode conductive layer patterns 228. Further referring to FIG. 11b, the insulating layer patterns 222 are disposed extending along the direction 260, so that the first electrode conductive layer patterns 228 and the second electrode conductive layer pattern 226 are parallel to each other. Also, an extending direction (the direction 260) of the first electrode conductive layer patterns 228 and the second electrode conductive layer pattern 226 may be vertical to an arranged direction of the first electrodes 218 and the second electrode 216 (the p-n junction arranged direction, that is, the direction 266). In one embodiment, the first electrode conductive layer patterns 228 and the second electrode conductive layer pattern 226 may comprise a conductive glue, solder-metallized copper ribbon used in the solar cell or the like or combinations thereof.

Please refer to FIG. 12, wherein next, a module packaging process may be performed, so that a pair of packaging material layers 231 entirely cover the top surface and the bottom surface of the semiconductor device unit 250, covering the first electrode conductive layer patterns 228, the second electrode conductive layer pattern 226, the insulating layer patterns 222 and the electron collection layer patterns 220. Next, a front plate 232 and a rear plate 234 are respectively disposed on the top surface and the bottom surface of the semiconductor device unit 250, covering the pair of packaging material layers 231. In one embodiment, the packaging material layers 231 may be formed of semiconductor device module packaging materials comprising ethylene vinyl acetate (EVA), polyvinyl chloride (PVC) or the like or combinations thereof. In one embodiment, the front plate 232 may be transparent, and materials of the front plate 232 may comprise polyester, polyolefin, polyethylene, polypropylene or polyimide. The description of one exemplary embodiment of a semiconductor device module package structure 500 of the invention is completed.

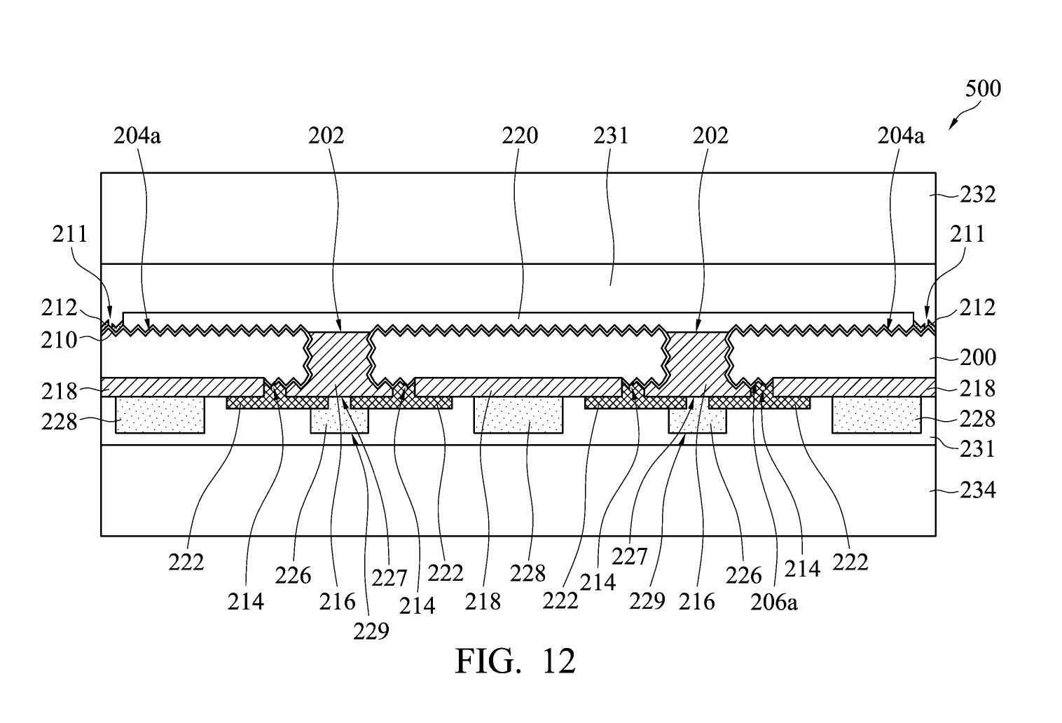

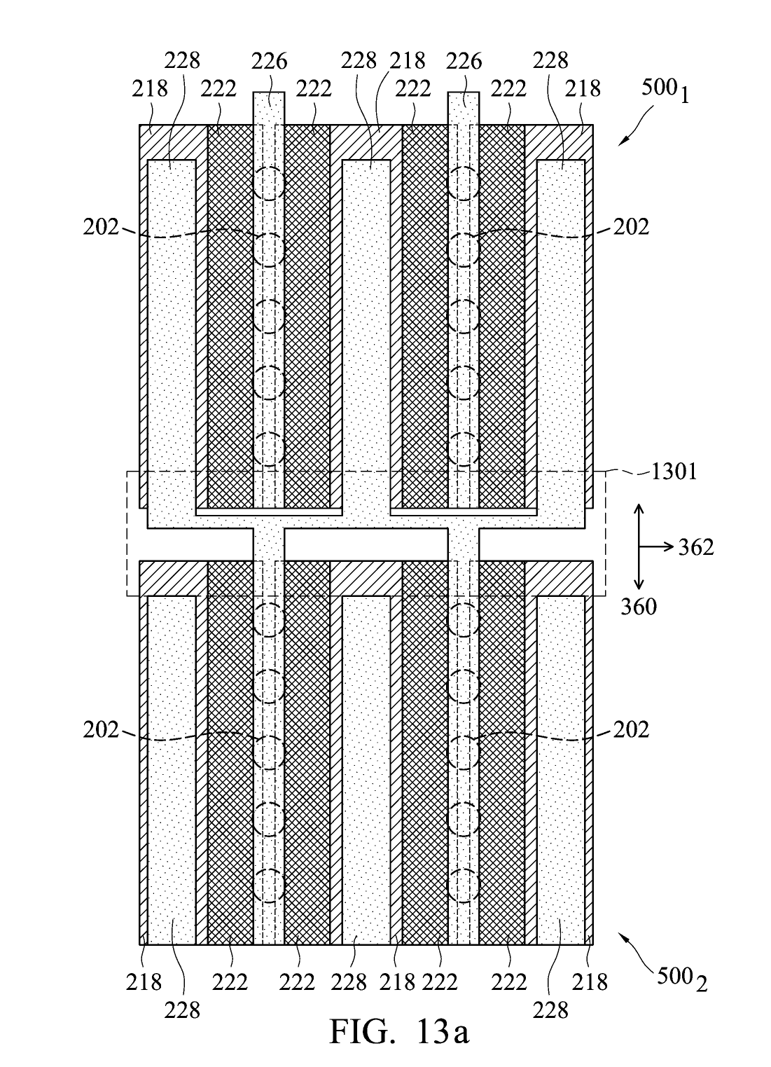

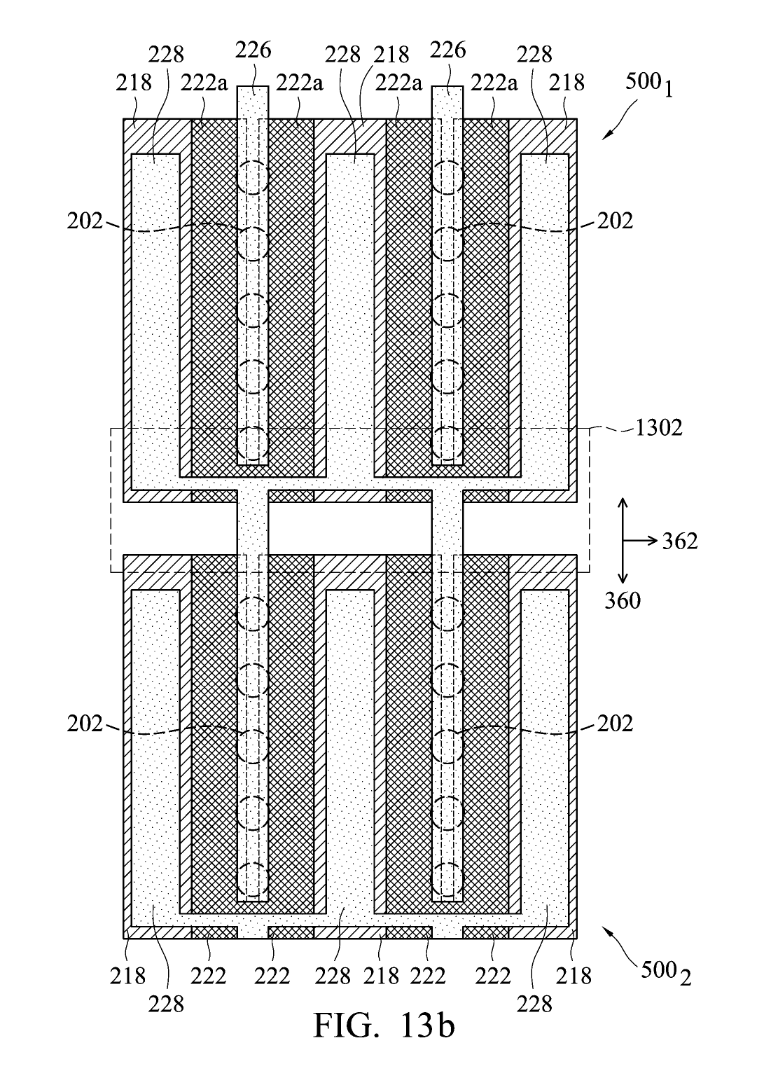

FIGS. 13a and 13b illustrate various exemplary embodiment of a series connection method of semiconductor device module package structures. FIGS. 13a and 13b are bottom views of two identical semiconductor device module package structures 500₁ and 500₂ to describe a series connection method for convenience, but the number of the semiconductor device module package structures used in a series connection is not limited by the disclosed embodiment. Also, the packaging material layers 231 and the rear plate 234 are not illustrated in FIGS. 13a and 13b for convenience. As shown in FIG. 13a, the semiconductor device module package structures 500₁ and 500₂ are in a series connection, wherein the first electrodes 218 of the semiconductor device module package structure 500₁ connect to the second electrodes 216 of the semiconductor device module package structure 500₂. That is to say, the first electrode conductive layer patterns 228 in different positions of the semiconductor device module package structure 500₂ connect to each other, and then the connected first electrode conductive layer patterns 228 of the semiconductor device module package structure 500₁ connect to the second electrode conductive layer patterns 226 at different positions of the semiconductor device module package structure 500₂. As shown in FIG. 13a, the first electrodes 218 and the second electrodes 216 of the semiconductor device module package structure 500₁ or 500₂ are arranged alternatively along a direction 362. Additionally, each of the first electrode conductive layer patterns 228 of the semiconductor device module package structure 500₁ series connect to each of the second electrode conductive layer patterns 226 of the semiconductor device module package structure 500₂ along a direction 360. Therefore, the series connection direction (the direction 360) of the semiconductor device module package structure 500₁ or 500₂ is not parallel to the arranged direction (the direction 362) of the first electrodes 218 and the second electrodes 216 in the semiconductor device module package structure 500₁ or 500₂. For example, the series connection direction (the direction 360) of the semiconductor device module package structure 500₁ or 500₂ is vertical to the arranged direction (the direction 362) of the first electrodes 218 and the second electrodes 216 in the semiconductor device module package structure 500₁ or 500₂. As shown in FIG. 13a, the region 1301 illustrates a connection portion of the first electrode conductive layer patterns 228 of the semiconductor device module package structure 500₁ and the second electrode conductive layer patterns 226 of the semiconductor device module package structure 500₂. The connection portion is in a space between the semiconductor device module package structures 500₁ and 500₂.

FIG. 13b illustrates another exemplary embodiment of a series connection method of semiconductor device module package structures. As shown in FIG. 13b, the semiconductor device module package structures 500₁ and 500₂ are series connected, wherein the region 1302 illustrates a connection portion of the first electrode conductive layer patterns 228 of the semiconductor device module package structure 500₁ and the second electrode conductive layer patterns 226 of the semiconductor device module package structure 500₂. The differences between the FIGS. 13a and 13b is that the connection portion as shown in FIG. 13b is directly underlying the semiconductor device module package structure 500₁. Therefore, the connection portion is separated from the second electrodes 216 directly overlying thereof through connected insulating layer patterns 222a. The connected insulating layer patterns 222a may prevent the first electrode conductive layer patterns 228 and the second electrode conductive layer patterns 226 in the semiconductor device module package structure 500₁ from shunting due to electrical connection to each other. Similarly to FIG. 13a, a series connection direction (the direction 360) of the semiconductor device module package structure 500₁ or 500₂ is not parallel to (such as vertical to) an arranged direction (the direction 362) of the first electrodes 218 and the second electrodes 216 in the semiconductor device module package structure 500₁ or 500₂.

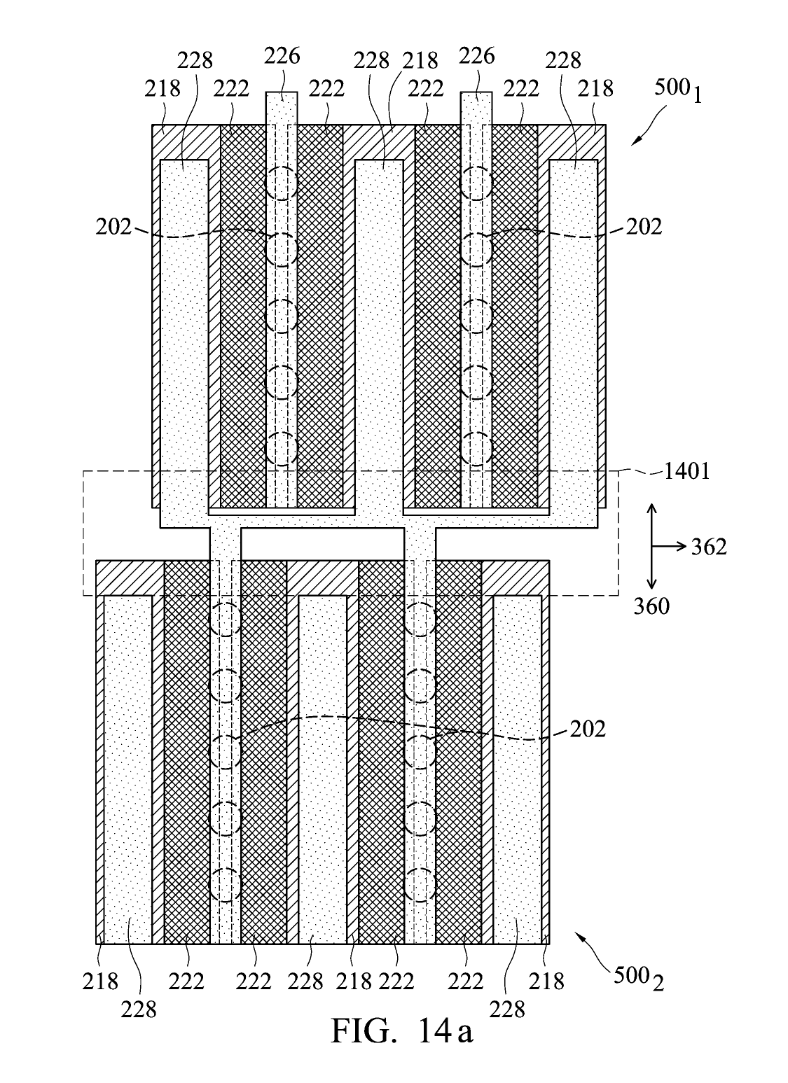

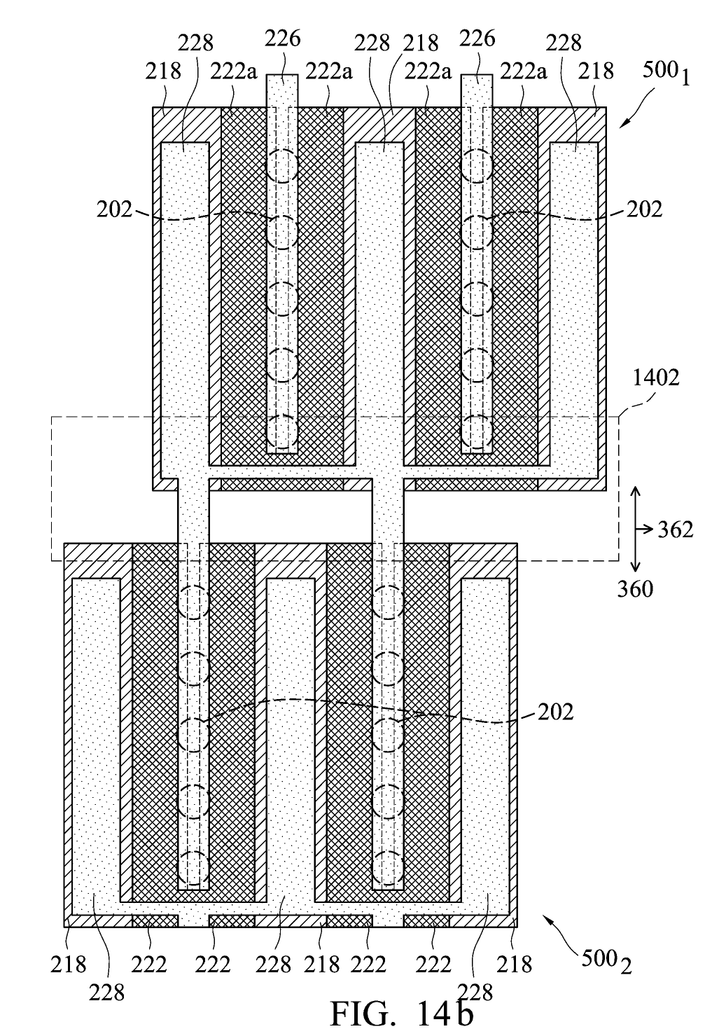

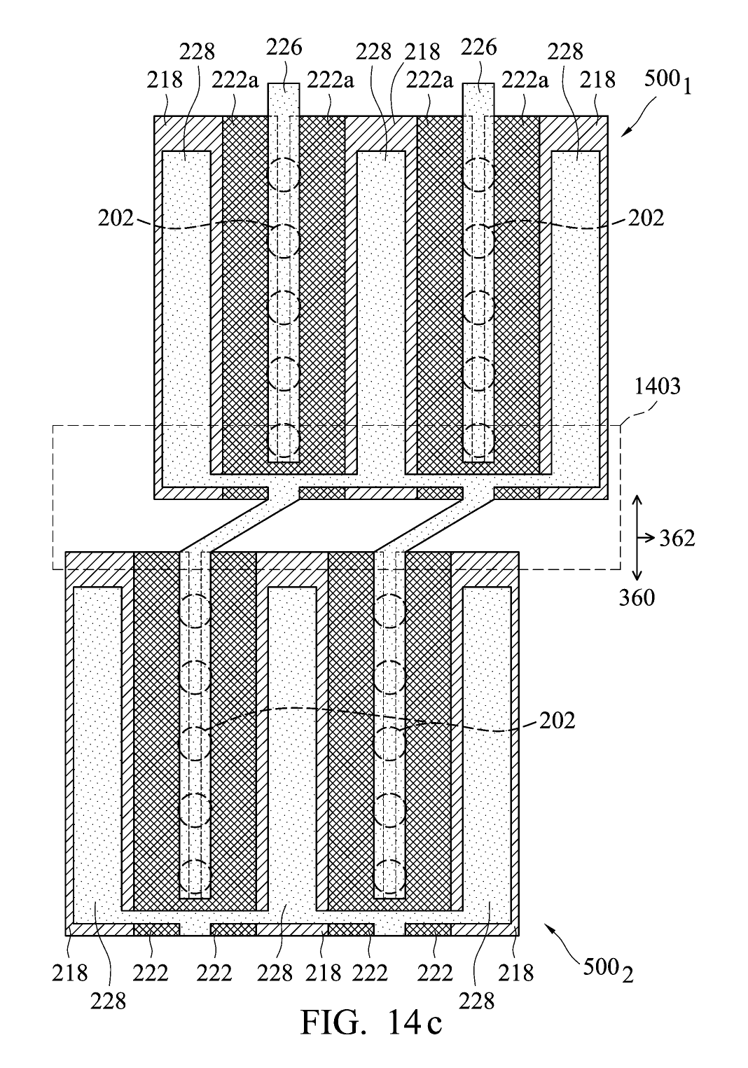

Reference to FIGS. 14a to 14c may also be made for the aforementioned method of the series connection direction and the electrode arranged direction being vertical to each other. FIGS. 14a to 14c illustrate various exemplary embodiments of a series connection method of semiconductor device module package structures. In regions 1401˜1403 as shown in FIGS. 14a to 14c, a connection portion of the first electrode conductive layer patterns 228 of the semiconductor device module package structure 500₁ and the second electrode conductive layer patterns 226 of the semiconductor device module package structure 500₂ may have various connection portion types. A space between the first electrode conductive layer patterns 228 of the semiconductor device module package structure 500₁ and the second electrode conductive layer patterns 226 of the semiconductor device module package structure 500₂ may be reduced, thereby reducing series resistance of the semiconductor device module package structures.

Exemplary embodiments of a series connection method of semiconductor device module package structures as shown in FIGS. 13a, 13b and 14a to 14c show structures in series connection derived from exemplary embodiments of a semiconductor device module package structure. Therefore, positions of the regions 1301, 1302, 1401, 1402 and 1403 (illustrate a connection portion of the first electrode conductive layer patterns 228 of the semiconductor device module package structure 500₁ and the second electrode conductive layer patterns 226 of the semiconductor device module package structure 500₂) as shown in FIGS. 13a, 13b and 14a to 14c are not limited by the disclosed embodiments. For example, the regions 1301, 1302, 1401, 1402 and 1403 may be disposed within or on the outside of the semiconductor device module package structure 500₁ or 500₂, wherein the connection portions disposed within he semiconductor device module package structure 500₁ or 500₂ as shown in the regions 1301, 1302, 1401, 1402 and 1403 may have a short length for the semiconductor device module package structures in a series connection. Therefore, less conductive material would be used.

TABLE 1
Cell performance comparisons between one exemplary embodiment of a semiconductor
device module package structure, for example, the semiconductor device
module package structure 500, and a conventional solar cell module package
structure without insulating layer patterns.

| | Power (W) | | | Filling factor (FF) | | |
|---|---|---|---|---|---|---|
| | before | after | difference | before | after | difference |
| | packaging | packaging | (%) | packaging | packaging | (%) |
| the semiconductor device | 9.53 | 9.81 | 1.55% | 73.10 | 72.64 | 0.46% |
| module package structure | | | | | | |
| 500 | | | | | | |
| the conventional solar cell | 9.81 | 9.29 | 5.33% | 74.00 | 70.49 | 3.51% |
| module package structure | | | | | | |

Table 1 illustrates cell performance comparisons between one exemplary embodiment of a semiconductor device module package structure, for example, the metal wrapped through (MWT) solar cell module package structure 500, and a conventional MWT solar cell module package structure without insulating layer patterns, wherein the measurement results of cell power and filling factor (FF) of four pieces of the semiconductor device module package structure 500 and four pieces of the conventional solar cell module package structure with a size of 12.3*12.3 cm² are shown. The filling factor (FF) in the context of solar cell technology is defined as the ratio of the maximum power Pₘₐₓ from the solar cell to the product of the open-circuit voltage (V_{oc}) and the short-circuit current (I_{sc}). That is to say, the FF is a measure of the “squareness” of the solar cell and is also the area of the largest rectangle which will fit in the IV curve. As shown, cell power loss of the semiconductor device module package structures 500 in a series connection was about 1.55%. Meanwhile, cell power loss of the conventional solar cell module package structures in a series connection was about 5.33%. The semiconductor device module package structures 500 reduced cell power loss by about 70.5% ([(5.33−1.57)/5.33]*100%=70.5%). Also, FF reduction of the semiconductor device module package structures 500 in a series connection was about 0.46% and FF reduction of the conventional solar cell module package structures in a series connection was about 3.516%. Compared to the conventional solar cell module package structures, the semiconductor device module package structure 500 had higher shunt resistance (Rsh) and smaller series resistance (Rs), thereby reducing FF loss during packaging processes. The semiconductor device module package structure 500 may have higher power. The aforementioned comparison results illustrate that the semiconductor device module package structure 500 may significantly improve the package loss of the cells in a series connection.

One exemplary embodiment of a semiconductor device module package structure 500 may have the following advantages: better photoelectric conversion efficiency due to the electrode conductive pads and the electrode conductive layer patterns being disposed on a surface opposite to an illuminated surface; elimination of an additional volume? serving as an isolation structure between cells; effective isolation of an anode electrode and cathode electrode from each other, as during the fabrication process of the solar cell module package structure, a pair of insulating layer patterns covers a connection position of the anode electrode and cathode electrode before formation of the conductive layer patterns used to series connect to the electrodes. Therefore, shunting of the insulating material, due to the anode electrode and cathode electrode being connected to each other, is avoided d; position tolerance of the electrode conductive layer pattern disposed thereon is increased without using alignment apparatuses and requiring highly accurate processes (refer to U.S. Pat. No. 5,972,732 and U.S. Pat. No. 5,951,786, wherein Sandia National Laboratories discloses a process comprising disposing a polymer material with circuit patterns between a cell and packaging material, and then aligning the cell with other package components to perform a highly accurate electrode alignment packaging process), therefore, one exemplary embodiment of a method for fabricating a semiconductor device module package structure is suitable for large-scale production; reduction of the resistance of the conductive layer patterns due to a large current conducting surface of the conductive layer patterns on the insulating layer patterns; high shunt resistance (Rsh) and small series resistance (Rs) due to control of the overlapping area between the insulating patterns and the anode or the cathode of the solar cell and low dielectric constant (k) of the insulating patterns; reduction of FF loss and package loss of the solar cell module package; a series connection direction of the various semiconductor device module package structures and an arranged direction of the first electrodes and the second electrodes in each of the semiconductor device module package structures are not parallel to each other (such as vertical to each other); and lastly, a simple fabrication process which is fully compatible with standard equipment.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device module package structure, comprising:
at least one semiconductor device unit having a top surface and a bottom surface, wherein the semiconductor device unit comprises:
a wafer having a plurality through holes;
a doped layer covering a top surface of the semiconductor device, and inner sidewalls of the through holes extending to a portion of a bottom surface of the wafer;
at least two first electrodes disposed on the bottom surface of the wafer and respectively on opposite sides of the through holes; and
a second electrode disposed on the bottom surface of the wafer, covering the doped layer and the through holes; and
at least two insulating layer patterns disposed on the bottom surface of the semiconductor device unit, overlapping a portion of one of the first electrodes and a portion of the second electrode; and
a second electrode conductive layer pattern disposed between the insulating layer patterns, electrically connecting to the second electrode.

2. The semiconductor device module package structure as claimed in claim 1, further comprising:
at least two first electrode conductive layer patterns respectively disposed on the first electrodes, wherein the first electrode conductive layer patterns are respectively separated from the second electrode conductive layer pattern.

3. The semiconductor device module package structure as claimed in claim 2, wherein the through holes are arranged along a first direction, and the insulating layer patterns are disposed extending along the first direction and overlapping with the through holes.

4. The semiconductor device module package structure as claimed in claim 2, wherein the top surface of the semiconductor device unit is an illuminated surface.

5. The semiconductor device module package structure as claimed in claim 3, wherein the semiconductor device unit further comprises:
a plurality of electron collection layer patterns respectively formed on the through holes, extended covering a portion of the top surface of the semiconductor device unit.

6. The semiconductor device module package structure as claimed in claim 4, wherein an overlapping area between each of the insulating layer patterns and one of the first electrodes or the second electrode is between 5% and 90% of the total surface area of one of the first electrodes or the second electrode.

7. The semiconductor device module package structure as claimed in claim 1, wherein the second electrode conductive layer pattern covers the insulating layer patterns.

8. The semiconductor device module package structure as claimed in claim 1, further comprising:
a pair of packaging material layers covering the top surface and the bottom surface of the semiconductor device unit; and
a front plate and a rear plate respectively disposed on the pair of packaging material layers covering the top surface and the bottom surface of the semiconductor device unit.

9. The semiconductor device module package structure as claimed in claim 1, wherein the semiconductor device module package structure is a solar cell module package, and the semiconductor device unit is a solar cell.

10. A series connection method of a semiconductor device module package structure, comprising:
providing at least two semiconductor device module package structures, such as those claimed in claim 2; and
connecting the first electrode conductive layer patterns of one of the semiconductor device module package structures and the second electrode conductive layer patterns of another one of the semiconductor device module package structures along a series connected direction to form a connection portion.

11. The series connection method of a semiconductor device module package structure as claimed in claim 10, wherein the series connected direction is vertical to an arranging direction of the first electrodes and the second electrode in each of the semiconductor device module package structures.

12. The series connection method of a semiconductor device module package structure as claimed in claim 10, wherein the connection portion is disposed in a space between the semiconductor device module package structures.

13. The series connection method of a semiconductor device module package structure as claimed in claim 10, wherein the connection portion is disposed directly under one of the semiconductor device module package structures, and the insulating layer patterns of the one of the semiconductor device module package structures directly above the connection portion are connected together.

14. A semiconductor device module package structure, comprising:
at least one semiconductor device unit having a top surface and a bottom surface, wherein the semiconductor device unit comprises:
a wafer having a plurality through holes;
a doped layer covering a top surface of the semiconductor device, and inner sidewalls of the through holes extending to a portion of a bottom surface of the wafer;
at least two first electrodes disposed on the bottom surface of the wafer, wherein the through holes are exposed from the first electrodes; and
a second electrode disposed on the bottom surface of the wafer, covering the doped layer and the through holes; and
at least two insulating layer patterns disposed on the bottom surface of the semiconductor device unit, overlapping a portion of one of the first electrodes and a portion of the second electrode; and
a second electrode conductive layer pattern disposed between the insulating layer patterns, electrically connecting to the second electrode.

15. The semiconductor device module package structure as claimed in claim 14, further comprising:
at least two first electrode conductive layer patterns respectively disposed on the first electrodes, wherein the first electrode conductive layer patterns are respectively separated from the second electrode conductive layer pattern.

16. The semiconductor device module package structure as claimed in claim 15, wherein the through holes are arranged along a first direction, and the insulating layer patterns are disposed extending along the first direction and overlapping with the through holes.

17. The semiconductor device module package structure as claimed in claim 15, wherein the top surface of the semiconductor device unit is an illuminated surface.

18. The semiconductor device module package structure as claimed in claim 17, wherein the semiconductor device unit further comprises:
a plurality of electron collection layer patterns respectively formed on the through holes, extended covering a portion of the top surface of the semiconductor device unit.

19. The semiconductor device module package structure as claimed in claim 14, further comprising:
a pair of packaging material layers covering the top surface and the bottom surface of the semiconductor device unit; and
a front plate and a rear plate respectively disposed on the pair of packaging material layers covering the top surface and the bottom surface of the semiconductor device unit.

20. The semiconductor device module package structure as claimed in claim 14, wherein the semiconductor device module package structure is a solar cell module package, and the semiconductor device unit is a solar cell.
